(19) United States
(12) Patent Application Publication
(10) Pub. No.: US 2005/0098427 A1
(43) Pub. Date: May 12, 2005

(54) RF coil design for improved film uniformity of an ion metal plasma source

(75) Inventors: Jui-Mu Cho, Hsin-chu (TW); Wen-Cheng Yang, Chung-Hwa (TW); Wen-Jung Yang, Fougshan City (TW); Y-Chih Lo, Hsin-chu (TW); Tay-Lang Huang, Miaoli Shien (TW); Te-Hung Hsieh, Miaoli County (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/706,565

(22) Filed: Nov. 11, 2003

(51) Int. Cl. C23C 14/34

(52) U.S. Cl. 204/192.12; 204/298.06

(57) ABSTRACT

The present disclosure provides a system and method for providing improved film uniformity from an ion metal plasma source. The system includes a deposition chamber and a coil. The coil is comprised of a first metal and includes opposite terminal ends disposed within the deposition chamber. At least one of the opposite terminal ends of the coil is angled less than ninety degrees.

### BACKGROUND

The present disclosure relates generally to the fabrication of semiconductor devices, and more particularly, to a method and system for optimizing and improving metal film uniformity on a semiconductor substrate.

Semiconductor device geometries have dramatically decreased in size since such devices were first introduced several decades ago. Since then, integrated circuits have generally followed the two year/half-size rule (often called Moore's Law), which means that the number of devices on an integrated circuit chip doubles every two years. Today's fabrication plants are routinely producing devices having 0.1 μm and even 90 nm feature sizes and smaller. As device size shrinks, many fabrication processes must be improved to maintain quality and reliability.

Metallization, which is the growth, formation, and/or deposition of a conducting material, is one such process that must be modified as device sizes decrease. During the metallization process, metal film quality and electrical reliability can be negatively impacted by defects and particles. These defects and particles can reduce device electrical yield and reliability. For example, spurious defects that cannot be etched can cause a short between metal lines. Another challenge for the metallization of smaller geometries is to provide adequate step coverage and good uniformity across the semiconductor substrates.

Today several different methods exist for depositing a thin conducting film on a semiconductor substrate. These include physical vapor deposition (PVD), electroplating, and chemical vapor deposition (CVD). PVD relates to a general family of methods for deposition of a thin film on a substrate and can include sputtering techniques or evaporation techniques under high vacuum conditions. Electroplating is typically used for the deposition of copper in large geometries but lacks good step coverage when used in very demanding geometries. CVD and plasma enhanced CVD (PECVD) can be very problematic in practice due to associated factors such as gas phase nucleation and many other particle formation mechanisms. Adequate step coverage for the newer, more process intensive geometries will require innovative improvements to the current industry processes.

### SUMMARY

A technical advance is achieved by a novel system and method for providing improved film uniformity from an ion metal plasma source. In one embodiment, the system is used for forming a metal film on a substrate. The system includes a deposition chamber and a coil. The coil is comprised of a first metal and includes opposite terminal ends disposed within the deposition chamber. At least one of the opposite terminal ends of the coil is angled less than ninety degrees.

In another embodiment, a method is provided for forming a metal film on a substrate. The method includes positioning a coil in a deposition chamber, the coil comprising a first metal and having opposite terminal ends. At least one of the opposite terminal ends is angled less than ninety degrees. The method also includes providing a radio frequency (RF) power to the coil to produce an electric field that is relatively uniform across the coil and sputtering portions from a target comprising a second metal through the coil and onto the substrate. In some embodiments, the coil defines a plane and at least a portion of at least one opposite terminal end is non-perpendicular to the plane.

In some embodiments, the relatively uniform electric field produces a film thickness that varies by 5% or less across the substrate.

In another embodiment, an ionized metal plasma system is provided for sputtering a metal film onto a wafer. The ionized metal plasma system includes a target source comprising a first metal, a chuck or heater for securing the wafer, and at least one coil positioned between the target source and the chuck or heater. The at least one coil is formed of a contiguous band of a first metal except for a relatively small gap in the band. The coil defining a transverse axis and the gap is non-aligned with the axis.

In another embodiment, a system is provided for forming a metal film on a substrate. The system includes a deposition chamber, a power supply for providing a radio frequency power, and a solid and contiguous coil disposed within the deposition chamber. The coil is connected to a single power terminal of the power supply.

### BRIEF DESCRIPTION OF THE DRAWINGS

FIG. 1 is a schematic cross-sectional view of an IMP chamber.

FIG. 2 is a plane view of a plane layout of a deposition cluster tool system used in the metallization process of semiconductor integrated circuit fabrication.

FIG. 3 is an ionized metal plasma (IMP) excitation coil according to a first embodiment of the present invention.

FIG. 4a is an IMP excitation coil according to a second embodiment of the present invention.

FIG. 4b is an IMP excitation coil according to a third embodiment of the present invention.

FIG. 4c is an IMP excitation coil according to a fourth embodiment of the present invention.

FIG. 4d is an IMP excitation coil according to a fifth embodiment of the present invention.

FIG. 5 is an IMP excitation coil according to a sixth embodiment of the present invention.

### DETAILED DESCRIPTION

The present invention provides a system and method for improving the uniformity of metal films deposited on a semiconductor substrate. It is understood, however, that the present disclosure provides specific examples to teach the broader inventive concept, and one of ordinary skill in the art can easily apply the teachings of the present disclosure to other semiconductor devices and structures. Also, it is understood that the system discussed in the present disclosure includes and/or utilizes many conventional structures in a new and unique manner

As semiconductor device geometries have continued to shrink below 500 nm and smaller, the equipment and the processes used for the sputtering of metal films have been improved to meet the new constraints. Also, wafer sizes are increasing to diameters at or above 300 mm. One process used to achieve these small device dimensions on relatively large wafers is an ionized metal plasma (IMP) deposition process. The IMP deposition process may be used to sputter deposit films of metal or metal-containing compounds. Using this process leads to better bottom and sidewall step coverage for a variety of device structures because of the directional flexibility afforded by the target/coil equipment used in the process.

Generally, IMP employs a sputter deposition source known as a target and a coil for generating metal ions from the sputtered material. The coil can be connected to a radio frequency (RF) generator to create a plasma which is a convenient source of energetic ions and activated atoms. The plasma generated by IMP is typically of a higher density than the plasma produced by standard PVD. The ions produced in the IMP process can be controlled to impact the substrate, rather than other areas of the process environment, by controlling the electrical potential drop between the bulk plasma and the substrate. The region of highest electrical potential drop occurs at the interface of the plasma and the substrate known as the plasma sheath. The plasma sheath region is a dark region where the velocity vector distribution of ions can be controlled to cause the ions to impact the substrate at an angle perpendicular to the substrate surface. Prior to the sheath region, there is another region known as the pre-sheath region where ions begin to be accelerated and are attracted away from the bulk plasma region. The ions will drastically accelerate upon entering the sheath region as the electrical potential drops, this acceleration can cause the metal ions to impinge upon the surface of the substrate. The velocity vector distribution and potential voltage drop across the sheath can be further controlled by an applied radio frequency (RF) or direct current (DC) bias to the substrate. Controlling the ion trajectories can lead to more control over film uniformity and step-coverage over a substrate.

Current IMP processes typically employ a coil that can be excited by RF to capacitively heat, inductively heat and/or wave heat the plasma which increases the plasma density and ionizes the sputtered metal. The currents produced by the coil provide Ohmic heat to the conducting plasma allowing the plasma to remain in a steady state. For example, current through a coil is supplied by an RF generator coupled to the coil through an impedance matching network, such that the coil acts as the first winding of a transformer. The plasma acts as a single turn second winding of a transformer. To maximize the RF energy being coupled from the coil to the plasma, the coil can be placed as close as possible to the plasma itself.

Commonly, the coil is composed of the same material as the target. For example, for depositing a tantalum or tantalum-containing film on a wafer, tantalum would be used as the coil material. During IMP deposition, the metal sputtered from the target can build up on the coil and can become a source of wafer contamination as the built up material can flake off of the coil or other surfaces and onto the wafer. To reduce this contamination and film uniformity problem, a process of knurling the surface of the coil and other surfaces inside the chamber can be employed to increase adhesion of any metal deposited on the coil. Another technique that can reduce contamination is to place the coil outside of a chamber wall which is in contact with the plasma. A third technique is called a helicon wave plasma, which can reduce contamination, but does not provide the benefits of attenuation avoidance and maximized energy transfer that can be derived from placing the coil as close as possible to the plasma generation area. Nevertheless, helicon wave plasmas can have improved plasma density profiles across the volume of the reactor due to the way in which electrons are heated in the plasma.

Film uniformity can also be highly dependent upon the characteristics of the plasma inside the IMP reactor, referred to as a plasma density profile. Plasma density profiles, which contribute to the film uniformity across a substrate, can be influenced by substrate potential bias uniformity and coil design, material, and placement. Film uniformity can also be influenced by many other factors such as sputter target placement, target size, chamber wall material and geometry, and substrate holder potential bias distribution. Current IMP reactor configurations attempt to achieve desirable film quality and uniformity across the substrate, but modifications are still needed to achieve high quality films through IMP.

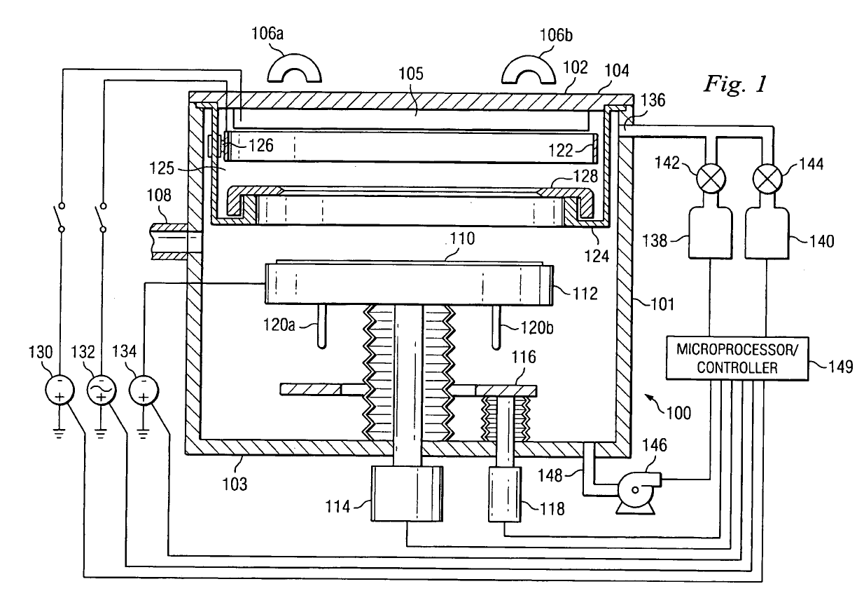

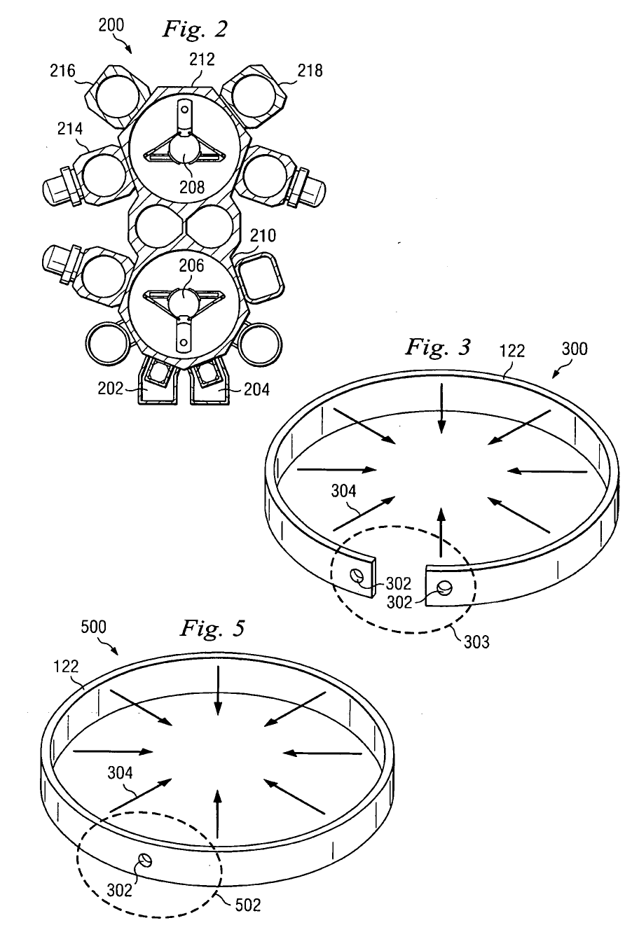

Referring now to FIG. 1, in this embodiment, an IMP chamber 100 with a target 105 and a coil 122 can, in a vacuum environment, generate a relatively high density plasma which is able to ionize a significant fraction of both the process gas and the sputtered material of the target 105. One example of an IMP chamber, the IMP Vectra, is available from Applied Materials, Inc. of Santa Clara, Calif. This IMP chamber can be integrated into an Endura platform, as shown in FIG. 2, also available from Applied Materials, Inc. The high density plasma can cause the sputtered target material to become ionized when in the vicinity of the coil 122. The ionized material develops a high electric field near the interface of the plasma with the substrate in the area known as the plasma sheath which accelerates the metal ions towards the substrate in a vector substantially perpendicular to the substrate surface. Biasing the substrate surface can provide even further control of the velocity distribution of the ionized sputtered material resulting in the deposition of a thin layer even in high aspect ratio features. In this embodiment, a coil 122 for generating plasma is located within the IMP chamber 100. Alternately, a plasma can be generated with the coil located outside of a shielded area 125 but in contact with a conductive shield 124. The induced energy from the coil 122 heats the electrons in the plasma and ionizes a significant portion of the sputtered metal atoms.

The chamber 100 further includes sidewalls 101, a lid 102, and a bottom 103. The lid 102 includes a target backing plate 104 which supports the target 105 of the material to be deposited. The target 105 can be a DC magnetron sputtering source made of a conductive material such as copper, tungsten, aluminum, titanium, tantalum, zirconium, vanadium, molybdenum or other materials. An opening 108 allows for the delivery and retrieval of substrates 110 to and from the chamber 100. The term “substrate” is broadly defined as an underlying material and can include a series of underlying layers, it is also not limited to size or shape. A substrate chuck 112 supports a substrate 110 in the chamber 100 and can be electrically grounded. The substrate chuck 112 can be mounted on a lift motor 114 that raises and lowers the substrate chuck 112 and the substrate 110. A lift plate 116 connected to a lift motor 118 raises and lowers pins 120a, 120b mounted in the substrate chuck 112. The pins 120a, 120b can come in contact with the substrate 110 and can raise and lower the substrate 110 relative to the surface of the substrate chuck 112.

A coil 122 can be mounted between the substrate chuck 112 and the target 105. In one embodiment, a quartz barrier (not shown) can be placed within the coil 122 to prevent deposition on the coil 122. The coil 122 can provide inductively coupled magnetic fields in the chamber 100 to assist in generating and maintaining a plasma between the target 105 and the substrate 110. The coil 122 can be made of the same or similar materials as the target 105. Power supplied to the coil 122 increases the density of the plasma which ionizes the sputtered material. The ionized material is then directed toward the substrate 110 for deposition. A shield 124 is disposed in the chamber 100 to shield the chamber sidewalls 101 from the sputtered material. The shield 124 also supports the coil 122 by coil supports 126. The coil supports 126 electrically insulate the coil 122 from the shield 124. The shield 124 can protect the chamber 100 from sputtered materials, and a clamp ring 128 can protect the outer edge of substrate 100 if the application requires.

Multiple power supplies can be used in this embodiment. A power supply 130 can deliver DC or RF power to the target 105 causing a processing gas to form a plasma near the target. Magnets 106a, 106b can be disposed behind the target backing plate 104 to increase the density of electrons in the plasma adjacent to the target 105 which increases ionization and the sputtering efficiency at the target. The magnets 106a, 106b generate magnetic field lines generally parallel to the face of the target and around which electrons can be trapped in spinning orbits. These spinning orbits increase the probability that an electron will collide with, and ionize, a gas atom for sputtering. A power supply 132, which can be an RF power supply, provides electrical power to the coil 122 which allows the power to couple with and increase the density of the plasma. Another power supply 134, which can be a DC power supply, biases the substrate chuck 112 with respect to the plasma and provides directional attraction or repulsion of the ionized sputtered material.

A processing gas, which can be an inert gas such as argon or a reactive gas such as nitrogen, can be supplied to the chamber 100 through a gas inlet 136 from gas sources 138, 140 and can be metered and controlled by responsive mass flow controllers 142, 144. A vacuum port 148 connected to a vacuum pump 146 can be used to exhaust the chamber 100 and to maintain the desired pressure in the chamber 100.

A controller 149 can generally control the functions of the power supplies 130, 132, 134; lift motors 114, 118; mass flow controllers 142, 144; vacuum pump 146; and other associated chamber components and functions. The controller 149 can execute system control software stored in a memory device (not shown), such a hard drive, and can include analog and digital input/output boards, interface boards, and stepper motor controller boards (not shown). Further, optical and/or magnetic sensors (not shown) can be used to move and determine the position of movable mechanical assemblies such as robotic arms (not shown).

Referring now to FIG. 2, a deposition cluster system 200 is one example of a processing tool that would utilize an IMP process reactor for the deposition of metal films onto conventional planar substrates. In this embodiment, the system 200 is an Endura platform from Applied Materials Inc. of Santa Clara, Calif. Such a deposition cluster system 200 can be used for the deposition of many different materials. The system 200 can be modified to accommodate film deposition on substrates other than conventional planar substrates. In the present embodiment, the deposition system 200 has two hexagonal shaped carrier chambers 210, 212 where substrates 110 may be transported by a robotic arm 206, 208 to a process chamber 214, 216, 218. Load lock chambers 202, 204 serve as a loading chamber for setting a substrate 110 in a carrier. The load locks 202, 204 can also serve as an unloading chamber for setting the substrate 110 in another carrier. As an example, the first vacuum chamber 214 could be utilized for the IMP deposition of a tantalum or tantalum nitride layer. The second vacuum chamber 216 could be used for the deposition of another barrier film, and the third vacuum chamber 218 could be used for deposition of a copper seed film.

Referring now to FIG. 3, a coil 122 used for the ionization of sputtered material atoms can be a simple metal band generally composed of the same material as the target 105. The coil 122 can be attached to a power source 132 (not shown in FIG. 3) at two electrical feeds through points 302 near terminated ends 303. In this figure, the terminated ends 303 of the coil 122 are generally at 90 degree angles and create a generally vertical gap. The coil 122 can sputter material on a substrate 110 due to the oscillating voltage which drives metal ions into the coil and away from the coil through a plasma sheath voltage drop. The coil 122, as depicted in FIG. 3, produces a voltage gap between the electrical feed through points 302, which can cause a non-uniform film area. As one example, an IMP TaN sputter deposition can often result in a film thickness that varies by 10% or greater, which is undesirable in semiconductor metallization for device geometries less than 200 nm or less.

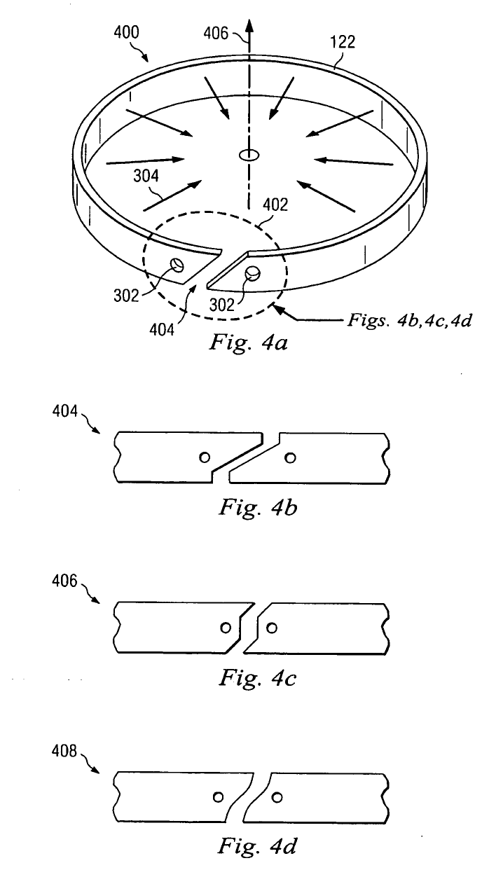

Referring now to FIG. 4a, the coil 122 in this embodiment is similar to the coil 122 in FIG. 3 except for the configuration of the terminated ends 303. The improved terminated ends 402 of the coil 122 in FIG. 4a are of a different shape than the terminal ends 303. The terminated ends 402 can be angled, such as at 45 degrees, with a narrow parallel gap 404 to improve the RF coupling and associated energy transfer to the plasma. This design of the terminated ends 402 can provide more uniform plasma heating which results in a more uniform plasma density within the volume of the coil 122. A uniform plasma can create a significant improvement in the uniformity of the deposited film. Continuous with the IMP TaN example, discussed with reference to FIG. 3. the coil 122 with terminal ends 402 can provide a film thickness that varies by 5% or less across the entire substrate 110. Several reasons may account for this improved uniformity. For one, plasma heating can become more capacitive than inductive due to the greater surface area around the terminal ends 402 of the present invention. Second, because the terminal ends 402 have a reduced gap, a more uniform electric field can be induced by the coil 122. The modified coil 122 may employ many different designs of the terminal ends.

Referring now to FIGS. 4b, 4c, and 4d, additional embodiments of the terminal ends include a angled and straight designs 404, 406 non-linear designs 408. Any one of these embodiments can be utilized in an IMP process environment to help improve the film uniformity over a substrate 110. The additional advantage of altering the terminal ends is that is it improves film uniformity in a very economical way. The tools and peripheral apparatus used to install and operate the coil need not be changed under the present invention. Additional embodiments include those where the gap 404 is not parallel with a transverse axis 406 passing through a central portion of the coil 122.

Referring now to FIG. 5. in another embodiment, the coil 122 can be replaced with a continuous coil 500 composed of the same material of that of the target 105 material, where the RF power would be supplied directly to the ring 500 with no electrical ground connection. The ring 500 can heat the plasma through capacitive coupling and employ, possibly, an electrical ground coupled to the substrate 110 and/or the ground chamber 100 and/or the chamber sidewalls 101. The continuous coil 500 can also sputter material on a substrate 110 due to an oscillating voltage which drives metal ions into the coil 122 and away from the continuous coil 500 through a plasma sheath voltage drop. As with the coil 122, sputtered material 304 can build up on the continuous coil 500.

Variations in the orientation of the IMP chambers and other components are possible. Other variations of the process equipment and environment are not limited by the above embodiments. IMP sputtering is not limited to the family of semiconductor device fabrication and may be adapted to treat other surfaces of any shape including planar, curved, spherical, or three-dimensional. Furthermore, IMP sputtering is not limited to circular wafers or substrates. The coil improvement for film uniformity on a surface is not limited to the specified equipment and process herein described and is not limited to a specific type of substrate, regardless of shape, size, and geometry. Accordingly, it is contemplated by the present invention to orient any and all of the components at achieve the desired support of substrates in a processing system.

The present invention has been described relative to a preferred embodiment. Improvements or modifications that become apparent to persons of ordinary skill in the art only after reading this disclosure are deemed within the spirit and scope of the application. It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. A system for forming a metal film on a substrate comprising:
a deposition chamber; and
a coil comprised of a first metal and having opposite terminal ends disposed within the deposition chamber;
wherein at least one of the opposite terminal ends is angled less than ninety degrees.

2. The system of claim 1 wherein the at least one opposite terminal end is forty-five degrees.

3. The system of claim 1 wherein the coil defines a plane and at least a portion of at least one opposite terminal end is non-perpendicular to the plane.

4. The system of claim 1 further comprising a target disposed within the deposition chamber wherein the target is comprised of a second metal.

5. The system of claim 1 wherein the metal film has a thickness less than 500nm.

6. The system of claim 4 wherein the first and second metals include the same metal material.

7. The system of claim 1 wherein the coil is of a diameter greater than or equal to 300 mm.

8. The system of claim 1 wherein the coil is non-circular.

9. A method for forming a metal film on a substrate comprising:
positioning a coil in a deposition chamber, the coil comprising a first metal and having opposite terminal ends, wherein at least one of the opposite terminal ends is angled less than ninety degrees;
providing a radio frequency (RF) power to the coil to produce an electric field that is relatively uniform across the coil; and
sputtering portions from a target comprising a second metal through the coil and onto the substrate.

10. The method of claim 9 wherein coil defines a plane and at least a portion of at least one opposite terminal end is non-perpendicular to the plane.

11. The method of claim 9 wherein the relatively uniform electric field produces a film thickness that varies by 5% or less across the substrate.

12. The method of claim 9 wherein the metal film has a thickness less than 500 nm.

13. The method of claim 9 wherein the first and second metals include the same metal material.

14. The method of claim 9 wherein the coil is of a diameter greater than or equal to 300 mm.

15. An ionized metal plasma system for sputtering a metal film onto a wafer, the system comprising:
a target source comprising a first metal;
a chuck for securing the wafer;
at least one coil positioned between the target source and the chuck, the at least one coil being formed of a contiguous band of a first metal except for a relatively small gap in the band, the coil defining a transverse axis and the gap is non-aligned with the axis.

16. The system of claim 15 wherein the metal film has a thickness less than 500nm.

17. The system of claim 15 wherein the first and second metals include the same metal material.

18. The system of claim 15 wherein the coil is of a diameter greater than or equal to 300 mm.

19. A system for forming a metal film on a substrate comprising:
a deposition chamber;
a power supply for providing a radio frequency power; and
a solid and contiguous coil disposed within the deposition chamber;
wherein the coil is connected to a single power terminal of the power supply.
